(19) United States
(12) Patent Application Publication
(10) Pub. No.: US 2010/0208445 A1
(43) Pub. Date: Aug. 19, 2010

(54) MULTI-LAYER WOVEN FABRIC DISPLAY

(75) Inventors: Sima Asvadi, Eindhoven (NL); Liesbeth Van Pieterson, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/682,265

(22) PCT Filed: Oct. 13, 2008
(86) PCT No.: PCT/IB08/54191

§ 371 Date: Apr. 9, 2010

(30) Foreign Application Priority Data
Oct. 16, 2007 (EP) 07118560.7

(51) Int. Cl. H05K 1/03; D03D 11/00

(52) U.S. Cl. 361/809; 442/206

(57) ABSTRACT

The present invention relates to textiles for photonic and electronic applications, particularly to multilayer textiles made of electrically conductive yarns for driving electrical components such as light emitting diodes connected to the textile. The light emitting diodes may be arranged in the form of an array in order to realize a flexible and foldable display. In the textile according to the present invention, insulating weft yarns are interwoven in a multilayer wrap (105) such that the electrically warp yarns (111) are partially covered by the insulating weft yarns (141), thereby preventing from short-circuit between electrically conductive yarns of the textile. In particular, the structure of the textile according to the present invention may be satin/sateen weave structure.

### FIELD OF THE INVENTION

The present invention relates to textiles for photonic and electronic applications. In particular, the present invention relates to multilayer textiles made of electrically conductive yarns for driving electrical components such as light emitting diodes connected to the textile.

### BACKGROUND OF THE INVENTION

Many types of textiles are already in use in our every day life, and new application fields for these textiles have emerged as electronics is now integrated into these textiles. For instance, photonic textiles such as fabrics comprising light emitting diodes (LED) open up a wide range of new interior and apparel applications, ranging from illumination to atmosphere creation to messaging. Very compact, low-power LED packages, available as so-called surface mounted devices, can be attached to the textile by e.g. gluing, snap button connection or stitching. This advantageously provides new types of e.g. foldable and flexible displays.

The fabric substrate of such displays is usually made of interwoven or embroidered electrically conductive and non-conductive yarns to build an electronic circuit to which electronic components are connected. As an example, document WO2006/129272 discloses a multilayer woven fabric display in which the fabric comprises non-insulated conductive yarns in a top layer and a bottom layer to carry electrical current to electronic components (LEDs) connected to the fabric, each of the electronic component corresponding to a pixel of the display. The use of non-insulated conductive yarns is advantageous since it facilitates the connection of the electronic components to the fabric and the realization of via connections between the top and bottom layer of the fabric. However, as the conductive yarns are not insulated, short-circuits may occur, e.g. when folding or wrinkling the fabric. A short-circuit between addressing lines of the fabric may modify the color displayed by the textile, which is undesirable.

To overcome the problem of electrical shorting, electrically conductive yarns having an outer insulating layer (insulated electrically conductive yarns) may be used. However, this alternative results in a need of removal of the outer insulating layer to connect electronic components to the fabric, which is cumbersome as it adds an extra processing step to the construction routine of the device during which the surrounding yarns could also be damaged due to the presence of chemicals and/or high temperature that might be needed for the removal of insulating coating.

A preferred textile would therefore be a textile which provides the advantages of easy connection of electronic components to the electrically conductive yarns and easy realization of via connections and, at the same time, reduces the risk of short-circuit.

Thus, there is a need for providing improved textiles structures, which would overcome some of these problems.

### SUMMARY OF THE INVENTION

An object of the present invention is to wholly or partly overcome the above disadvantages and drawbacks of the prior art and to provide improved multilayer textiles.

The present invention provides a multilayer textile for photonic and electronic applications such as a foldable and flexible display. By reducing the risk of short circuit in the textile, the performance of the display becomes stable and little sensitive to mechanical deformation such as e.g. folding or wrinkling that could involve simultaneous bending, shear and tension of the textile material.

Hence, according to a first aspect of the present invention, a textile formed of interwoven electrically conductive and insulating yarns (or fibres or strikes) arranged along a warp direction and a weft direction is provided. The textile includes a multilayer warp comprising a first layer of electrically conductive yarns electrically separated from each other by at least one electrically insulating yarn, a second layer of electrically insulating yarns, and a third layer of electrically insulating yarns arranged between the first and second layers. The first and second layers define a first face and a second face, respectively, of the multilayer warp. The textile further includes a weft comprising electrically conductive weft yarns electrically separated from each other by at least one electrically insulating weft yarn. At least one of the electrically insulating weft yarns crosses the first face and covers the electrically conductive warp yarns of the first layer.

The present invention is based on an insight that the conductive warp or weft yarns of a textile exposed to the outside of the textile can be covered by the insulating weft or warp yarns respectively, by long floats. The insulating yarns are interwoven in the multilayer structure in order to partially cover the exposed conductive yarns on the face of the fabric.

An advantage of the present invention is that the risk for short circuit is reduced when e.g. bending, buckling, folding or wrinkling the textile since the electrically conductive warp yarns of the first layer are partially covered by the insulating weft yarns. The zones where insulating weft yarns do not cover the conductive yarns of the warp or where no insulating warp yarn covers the conductive weft yarns may be used for connection of electronic components, thereby resulting in a completely electrically isolated surface after assembly of the components.

The interweaving of the electrically insulating yarns provides insulating floats at the first face of the textile, thereby preventing electrically conductive yarns of the first layer from short-circuiting.

Another advantage of the present invention is that the textile facilitates the connection of electronic components as the conductive yarns are non insulated, i.e. there is no need of removing an outer layer of the yarn before the connection of a component.

Another advantage of the present invention is that the creation or realization of crossover points or via connections from one face of the textile to another is facilitated as an electrical contact between a conductive yarn of the warp and a conductive yarn of the weft readily is established by a physical contact. There is no need for further processing of the conductive yarns nor for advanced structure.

According to an embodiment, at least one electrically conductive weft yarn is interwoven between the first and second faces of the multilayer warp and crosses at least one of the first and second faces by means of a loop arranged around a selected warp yarn of at least one of the first and second layers, respectively.

According to an embodiment, the second layer of the multilayer warp may comprise conductive yarns, which enables forming of a double side display since electronic components may be connected at both sides of the textile. In the present embodiment, the interweaving of the electrically insulating weft yarns prevents short-circuiting between electrically conductive weft yarns and electrically conductive warp yarns, between electrically conductive warp yarns within one of the layers, and between electrically conductive warp yarns of the first layer and electrically conductive warp yarns of the second layer. In addition, short-circuiting between electrically conductive weft yarns of the first layer and electrically conductive warp yarns of the second layer is avoided by means of the third layer comprising electrically insulating yarns.

According to an embodiment, the selected warp yarn of at least one of the first and second layers is electrically insulating, thereby defining, by means of the loop, first electrical connection zones electrically separated from the electrically conductive warp yarns of the first and second layers, respectively, by at least one insulating warp yarn in each layer of the multi-layer warp. Further, second connection zones are defined at neighboring electrically conductive warp yarns of at least one of the first and second layers, respectively. Thus, first and second electrical connection zones are defined in at least one of the faces of the multilayer warp if the selected warp yarn is insulated.

According to another embodiment, the selected warp yarn is electrically conductive, thereby forming a via in the textile. Crossover points are points at which an electrically conductive weft yarn forms a loop around an electrically conductive warp yarn, thereby making an electrical contact between the electrically conductive warp and weft yarns. These electrically conductive crossover points may be used to direct or lead current from the driver electronics to the electrically conductive yarns of the regions of the textile where electronic components are attached.

According to an embodiment, at least one electronic component is connected via the first and second electrical connection zones of either one of or both the first and second layers. Such a component may be a sensor, an actuator, an integrated circuit or an optoelectronic device such as a light emitting diode. As an alternative, a plurality of electronic components may be connected to the textile and arranged in the form of an array or matrix, thereby forming a display. Each of the electronic components of the array may be addressable by means of addressing lines, i.e. electrically conductive yarns whose function is to carry electrical signals to a particular component or specific regions of the textile. The connection to and between addressing lines may be performed by means of crossover points. In addition, the textile may also comprise a radio frequency antenna comprising woven conductive yarns in electrical connection with and for remote communication with the electronic components.

According to an embodiment, each of the insulating weft yarns covers several adjacent warp yarns of at least one of the first and second layers, thereby forming a float. In particular, the weft yarns may be interwoven in the multilayer warp according to a satin or sateen weave structure for the entire fabric or for a part of the fabric combined with a plain weave structure. In the sateen/satin weave structure, some of the insulating weft yarns are interwoven within the first face and the second face without covering the electrically conductive warp yarns, thereby defining electrical connection zones in the electrically conductive yarns of the first or second layers.

Further objectives of, features of, and advantages with, the present invention will become apparent when studying the following detailed disclosure, the drawings and the appended claims. Those skilled in the art will realize that different features of the present invention can be combined to create embodiments other than those described in the following.

### BRIEF DESCRIPTION OF THE DRAWINGS

The above, as well as additional objectives, features and advantages of the present invention, will be better understood through the following detailed description and illustrative drawings, on which:

FIG. 1 shows a cross-sectional view of a textile illustrating the weaving of an electrically conductive weft yarn in a multilayer warp according to an embodiment of the present invention;

FIG. 2 shows a cross-sectional view of a textile illustrating the weaving of an insulating weft yarn in a multilayer warp according to an embodiment of the present invention, which embodiment may be used in combination with the embodiment shown in FIG. 1;

FIG. 3 shows a cross-sectional view of a textile illustrating the weaving of an electrically conductive weft yarn in a multilayer warp according to another embodiment of the present invention;

FIG. 4 shows a cross-sectional view of a textile illustrating the weaving of an insulating weft yarn in a multilayer warp according to an embodiment of the present invention, which embodiment may be used in combination with the embodiment shown in FIG. 3;

FIG. 5 shows a cross-sectional view of a textile illustrating the weaving of an electrically conductive weft yarn in a multilayer warp according to another embodiment of the present invention;

FIG. 6 shows a cross-sectional view of a textile illustrating the weaving of an electrically insulating weft yarn in a multilayer warp according to an embodiment of the present invention, which embodiment may be used in combination with the embodiment shown in FIG. 5;

FIG. 7 shows a cross-sectional view of a textile illustrating the weaving of an electrically conductive weft yarn in a multilayer warp according to another embodiment of the present invention; and

FIG. 8 shows a top view of a schematic representation of a textile according to an embodiment of the present invention, wherein the weaving structure is satin or sateen.

### DETAILED DESCRIPTION OF THE INVENTION

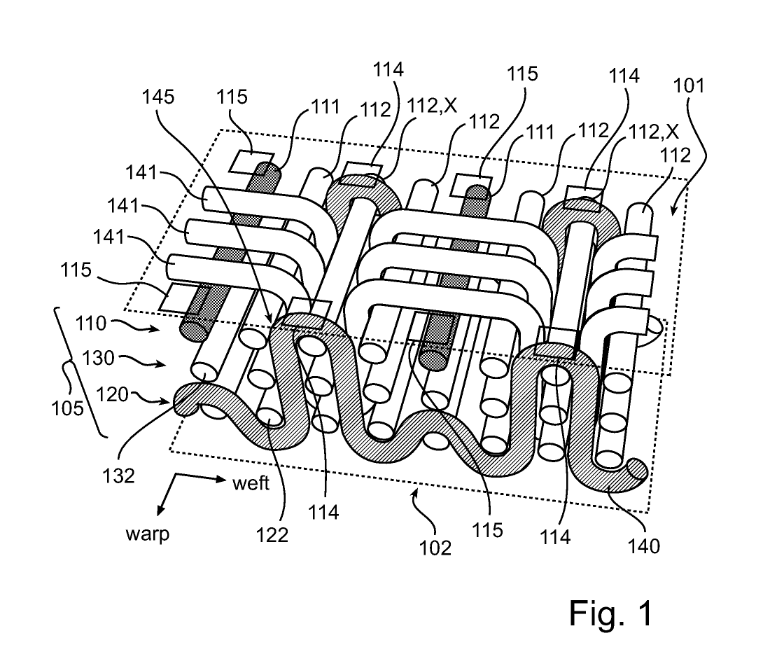

With reference to FIG. 1, a first embodiment of the present invention will be described.

FIG. 1 shows a cross-sectional view of a textile 100 illustrating the weaving of an electrically conductive weft yarn 140 in a multilayer warp 105. The multilayer warp 105 of the textile (or fabric) 100 comprises a first layer 110, a second layer 120 and a third layer 130 arranged between the first layer 110 and the second layer 120. The yarns 111 and 112 of the first, second and third layers 110, 120 and 130 are arranged along a so-called warp direction, thereby defining the multilayer warp 105. The first layer 110 comprises electrically conductive yarns 111 electrically isolated from each other by at least one electrically insulating yarn 112. In the present embodiment, two adjacent electrically conductive warp yarns 111 of the first layer 110 are electrically separated by three electrically insulating warp yarns 112. The second and third layers 120 and 130 comprise electrically insulating yarns 122 and 132, respectively. The first layer 110 and the second layer 120 define a first face 101 and a second face 102, respectively, of the multilayer warp 105.

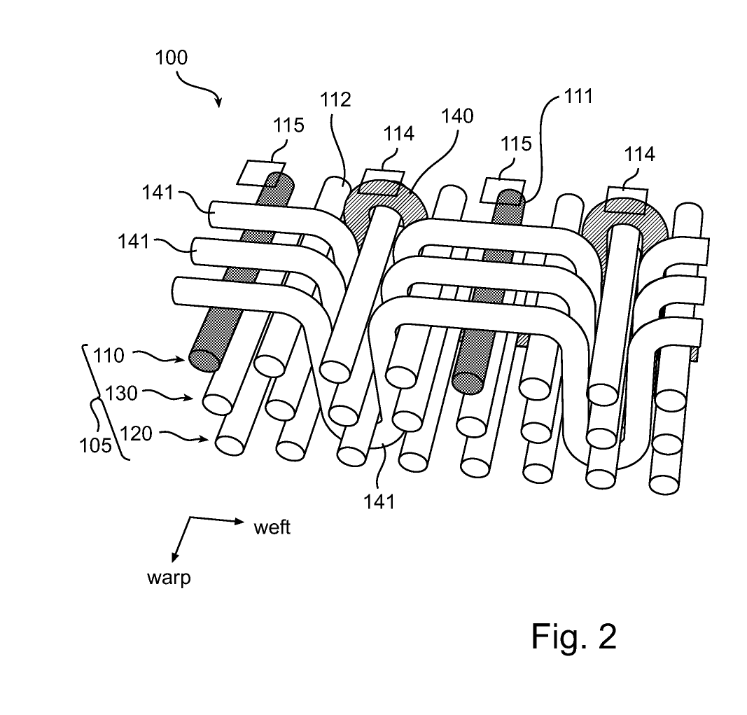

The textile 100 also comprises a weft comprising electrically conductive yarns 140 electrically separated from each other by at least one insulating weft yarn 141 (also shown in FIG. 2). The weft yarns are arranged along a so-called weft direction which is different from the warp direction. As an example, the weft and warp directions may be orthogonal to each other. However, any angle may be formed between these two directions. The electrically conductive weft yarn 140 is interwoven within the yarns of the multilayer warp 105, between the first face 101 and the second face 102, and crosses the first face 101 by means of a loop 145 arranged around a selected warp yarn X of the first layer 110.

FIG. 2 shows a cross-sectional view of the textile 100 illustrating the weaving of the insulating weft yarns 141 in the multilayer warp 105 according to an embodiment of the present invention, which embodiment may be used in combination with the embodiment described with reference to FIG. 1. However, it is to be noted that the insulating weft yarns of the embodiment described with reference to FIG. 1 may be interwoven in a different manner than that shown in FIG. 2. At least some of the electrically insulating weft yarns 141 cross the first face 101 of the multilayer warp 105 and cover the electrically conductive warp yarns 111 of the first layer 110 in order to prevent short-circuiting between the electrically conductive warp yarns 111 of the first layer 110 mutually, and between the electrically conductive warp yarns 111 and the zones of the electrically conductive weft yarn 140 located at the second face 102 of the multilayer warp 105, e.g. when wrinkling the textile. However, components will normally be attached to the zones of the electrically conductive weft yarn 140 located at the second face 102, thereby avoiding short-circuiting at these positions. In the example shown in FIGS. 1 and 2, all of the electrically insulating weft yarns cover the electrically conductive warp yarns.

In the present embodiment (as shown in FIGS. 1 and 2), the selected warp yarn X is one of the electrically insulating warp yarns 112 of the first layer 110, thereby defining, by means of the loop 145, first electrical connection zones 114 at the first face 101 of the multilayer warp 105 (or textile 100). The first electrical connection zones 114 are electrically separated from the electrically conductive warp yarns 111 of the first layer 110 by at least one insulating warp yarn 112, thereby defining second electrical connection zones 115 at neighboring electrically conductive warp yarns 111 of the first layer 110. The second electrical connection zones 115 are electrically separated from each other by means of the insulating weft yarns 141. It is also possible to form second electrical connection zones if only some of the insulating weft yarns cover the electrically conductive warp yarns, which will be described with reference to FIG. 8 later. In the present embodiment, the insulating weft yarns 141 cross the first face 101 of the multilayer warp 105 and cover three adjacent warp yarns of the first layer 110, thereby forming a float. The three adjacent warp yarns comprise one electrically conductive yarn 111 arranged between two electrically insulating warp yarns 112. However, it is to be noted that the electrically insulating weft yarns 141 may be interwoven to only cover the electrically conductive warp yarns of the first layer 110 and not the insulating warp yarns. Similarly, the interweaving of an electrically insulating weft yarn 141 may be different from the interweaving of its adjacent electrically insulating weft yarns. An example in which the interweaving of adjacent insulating weft yarns differ form one to another and in which the electrically conductive warp yarns are partially covered by the insulating weft yarns will be described with reference to FIG. 8.

Electronic components, such as sensors, actuators, integrated circuits and/or optoelectronic devices, may be connected to the textile 100 via the first and second electrical connection zones 114 and 115 at the first face 110 of the multilayer warp 105. In particular, the electronic components may be light emitting diodes. In a preferred embodiment, the electronic components or light emitting diodes are arranged in the form of an array or matrix, thereby realizing a display. Each of the components may be individually addressable by means of addressing lines (which are electrically conductive warp yarns of the textile) and correspond to one pixel of the display. Further, the textile may comprise a radio frequency antenna comprising woven conductive yarns in electrical connection to and for remote communication with the electronic components.

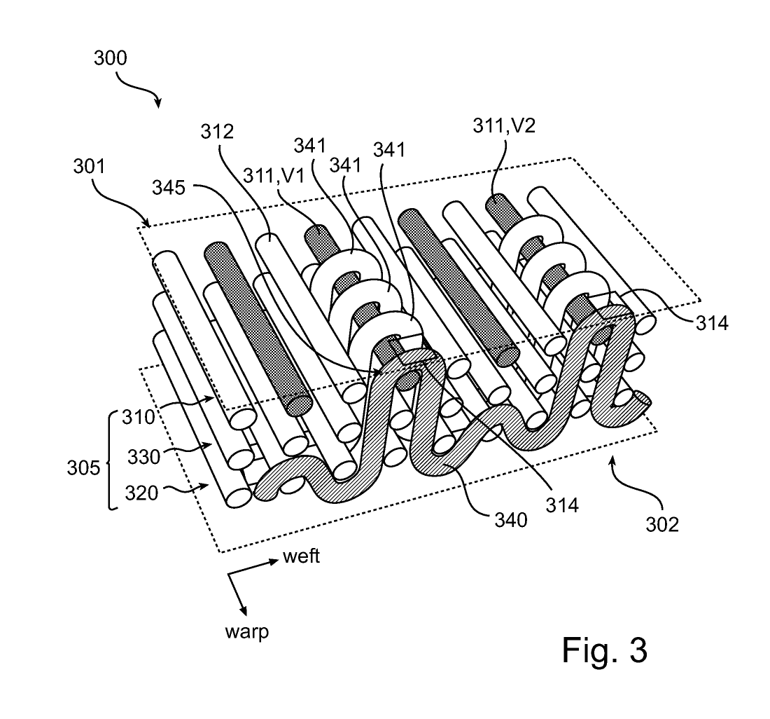

With reference to FIG. 3, another embodiment of the present invention will be described.

FIG. 3 shows a cross-sectional view of a textile 300 illustrating the weaving of an electrically conductive weft yarn 340 in a multilayer warp 305 of the textile 300. The textile 300 is equivalent to the textile 100 described with reference to FIGS. 1 and 2 except that the electrically conductive warp yarns 311 of the first layer 310 are electrically isolated from each other by only one electrically insulating warp yarn 312. The textile 300 comprises a multilayer warp 305 comprising a first layer 310 defining a first face 301 of the multilayer warp, a second layer defining a second face 302 of the multilayer warp, and a third layer 330 arranged between the first and second layers 310 and 320. The electrically conductive weft yarn 340 is interwoven between the first and second faces 301 and 302 and crosses the first face 301 by means of a loop 345 arranged around a selected warp yarn Y of the first layer 310. In the present embodiment, the selected warp yarn Y is electrically conductive, thereby defining a crossover point 314 in the textile. This crossover point 314 may be used to carry signals or electrical current from one electrically conductive yarn V1 to another electrically conductive yarn V2 via the electrically conductive weft yarn 340 or to maintain the same potential at two or more electrically conductive warp yarns V1 and V2 located at different regions of the textile 300. The crossover points 314 are also useful for connection of addressing lines to the bus lines or the controlling electronics. Crossover points (314) may be arranged in either the first, second or middle layer. However, it is preferable to arrange the crossover points in the third layer (middle layer) for not exposing a conductive point that is not used for connecting a component.

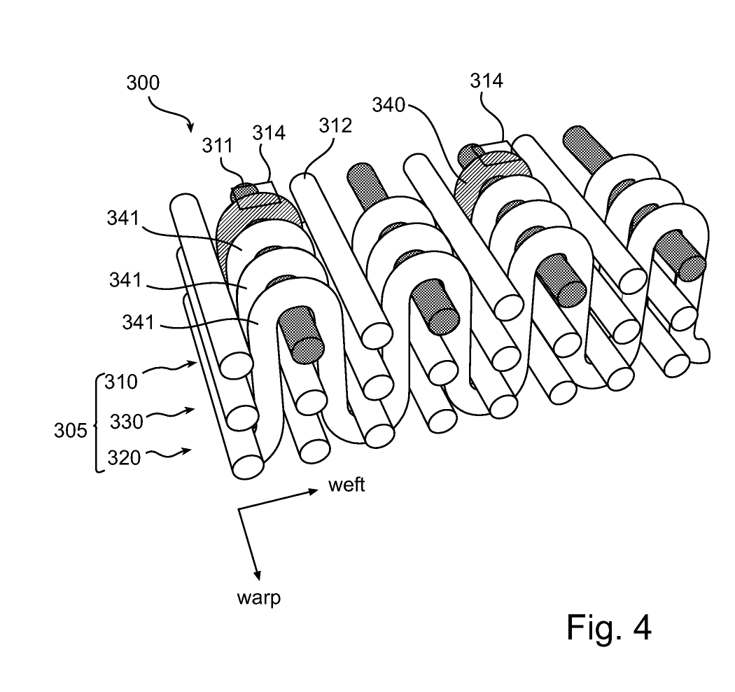

FIG. 4 shows a cross-sectional view of the textile 300 illustrating the weaving of an insulating weft yarn 341 in the multilayer warp 305 according to an embodiment of the present invention, which embodiment may be used in combination with the embodiment shown in FIG. 3. However, it is to be noted that the insulating weft yarns of the embodiment described with reference to FIG. 3 may be interwoven in a different manner than that shown in FIG. 4. In the embodiment shown in FIG. 4, the electrically insulating weft yarns 341 cross the first face 301 of the multilayer warp 305 and cover the electrically conductive warp yarns 311 of the first layer 310 in order to prevent short-circuiting with other electrically conductive warp yarns 314 and with the zones of the electrically conductive weft yarn 340 located at the second face 302 of the multilayer warp 305, e.g. when wrinkling the textile.

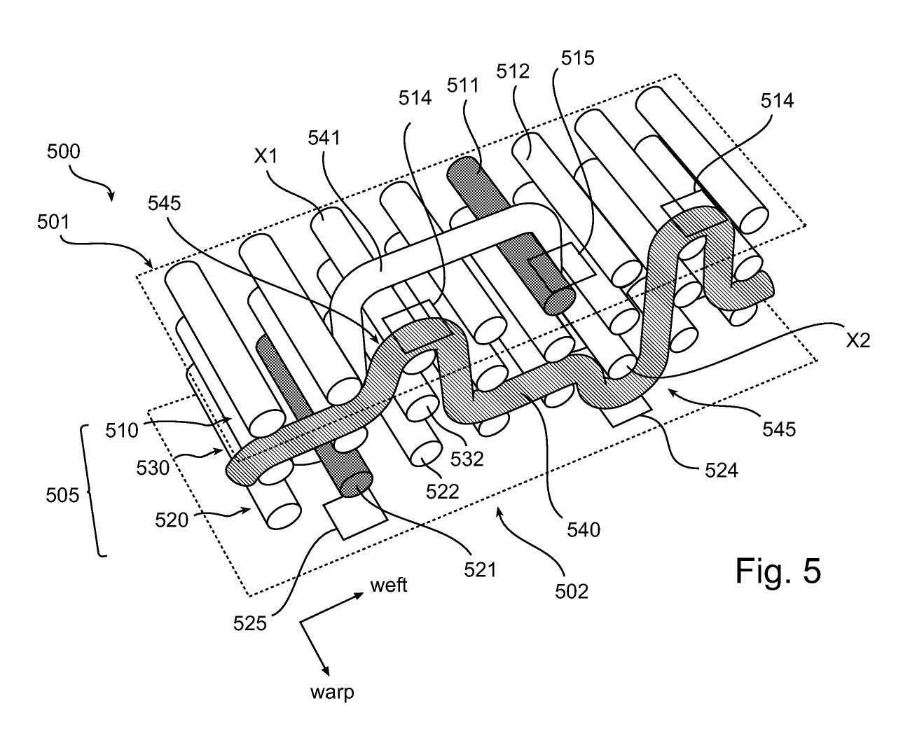

With reference to FIG. 5, another embodiment of the present invention will be described.

FIG. 5 shows a cross-sectional view of a textile 500 illustrating the weaving of an electrically conductive weft yarn 540 in a multilayer warp 505 of the textile 500. The textile 500 is equivalent to the textile 100 described with reference to FIG. 1 except that the electrically conductive warp yarns 511 of the first layer 510 are electrically isolated from each other by more than three electrically insulating yarns 512 and that the second layer 520 further comprises electrically conductive warp yarns 521 electrically separated from each other by at least one electrically insulating warp yarn 522. The textile 500 comprises a multilayer warp 505 comprising a first layer 510 defining a first face 501 of the multilayer warp, a second layer 520 defining a second face 502 of the multilayer warp, and a third layer 520 comprising electrically insulating yarns 532 arranged between the first and the second layers 510 and 520 to electrically isolate the first layer 510 from the second layer 520. The electrically conductive weft yarn 540 is interwoven between the first face 501 and the second face 502 and crosses the first face 501 by means of a loop 545 arranged around a selected warp yarn X1 of the first layer 510 and the second face 502 by means of a loop 545 arranged around a selected warp yarn X2 of the second layer 520. In the present embodiment, the selected warp yarns X1 and X2 are electrically insulating, thereby defining first electrical connection zones 514 and 524 at the first and second layers 510 and 520, respectively.

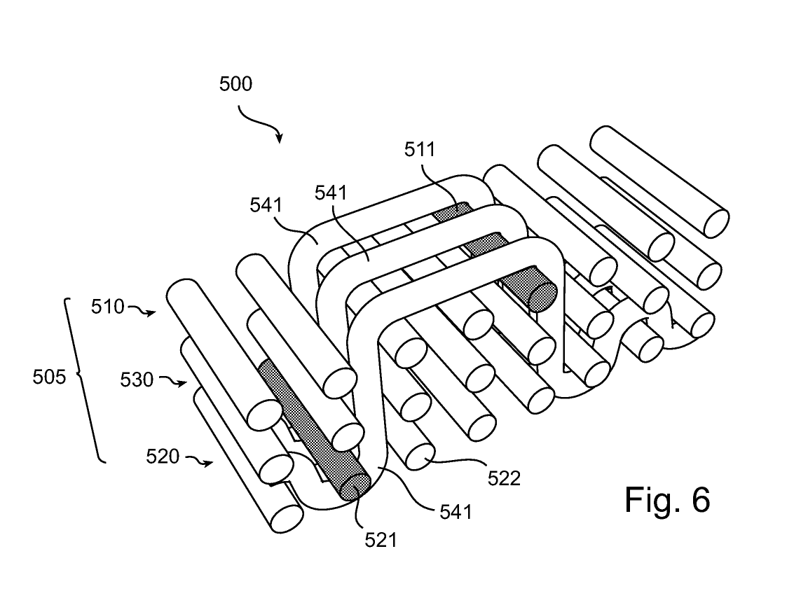

FIG. 6 shows a cross-sectional view of the textile 500 illustrating the weaving of an insulating weft yarn 541 in the multilayer warp 505 according to an embodiment of the present invention, which embodiment may be used in combination with the embodiment shown in FIG. 5. However, it is to be noted that the insulating weft yarns of the embodiment described with reference to FIG. 5 may be interwoven in a different manner than that shown in FIG. 6. In the embodiment shown in FIG. 6, the insulating weft yarns 541 are interwoven between the first face 501 and the second face 502 and cross the first and second faces to cover the electrically conductive warp yarns 511 and 521 of the first and second layers, respectively. In the present embodiment, the electrically insulating weft yarns 541 cover the electrically conductive warp yarns to prevent electrical short-circuiting between electrically conductive warp yarns of the first and second layers, between electrically conductive warp yarns within either one of the first and second layers, and between the electrically conductive weft yarn and the electrically conductive warp yarns of the first and second layers. The configuration described with reference to FIGS. 5 and 6 enables building of a double side display when connecting electronic components to the first and second electrical connection zones at both the first and second faces 501 and 502 of the textile.

Electronic components may be connected to the first and second electrical connection zones in a similar manner as that described above with reference to FIGS. 1 and 2.

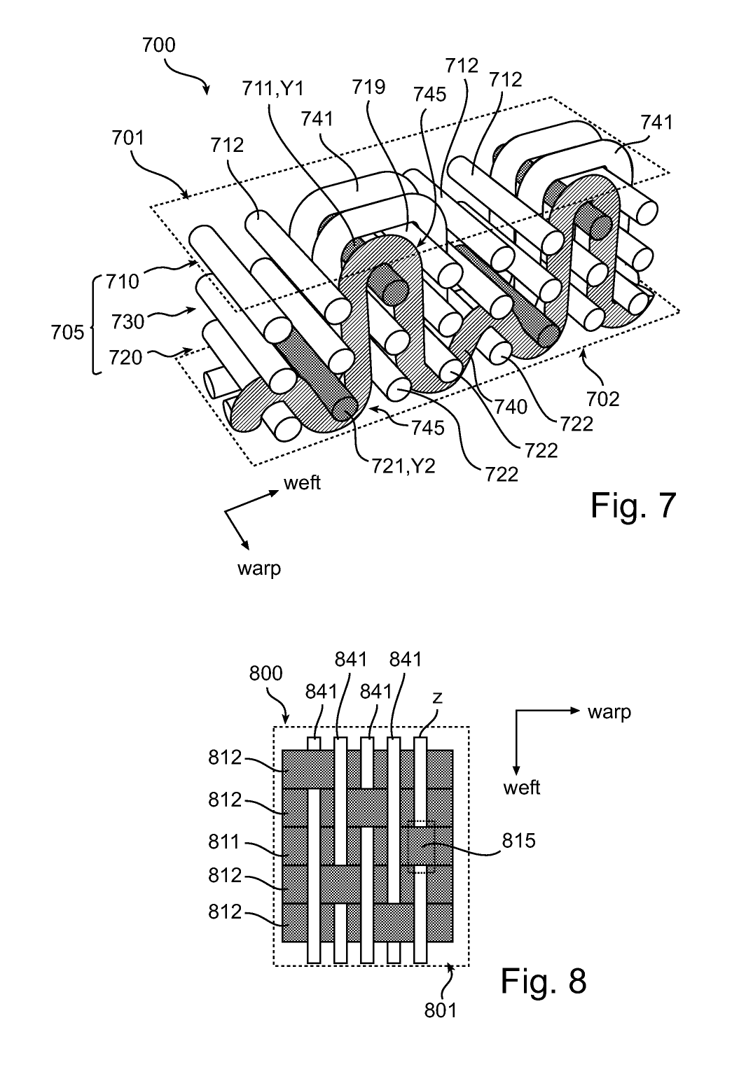

With reference to FIG. 7, another embodiment of the present invention will be described.

FIG. 7 shows a cross-sectional view of a textile 700 illustrating the weaving of an electrically conductive weft yarn 740 in a multilayer warp 705 of the textile 700. The textile 700 is equivalent to the textile 500 described with reference to FIGS. 5 and 6 except that the electrically conductive warp yarns 711 and 721 are electrically isolated from each other, within the first layer 710 and the second layer 720, respectively, by three electrically insulating yarns 712 and 722, respectively. The electrically conductive weft yarn 740 is interwoven between a first face 701 and a second face 702 of the multilayer warp 705 and crosses the first and second faces 701 and 702 by means of loops 745 arranged around electrically conductive warp yarns Y1 and Y2 of the first and second layers 710 and 720, respectively, to connect an electrically conductive warp yarn Y1 of the first layer 710 to an electrically conductive warp yarn Y2 of the second layer 720, thereby defining a via connection between the first face 701 and the second face 702 of the multilayer warp 705. The electrically insulating weft yarns 741 are interwoven between the first face 701 and the second face 702 and cross these faces to cover the electrically conductive warp yarns of the first 710 and second layers 720, respectively, in a similar manner as that described with reference to FIG. 6.

With reference to FIG. 8, another embodiment of the present invention will be described.

FIG. 8 shows a top view of a schematic representation of a textile 800 according to an embodiment of the present invention, wherein the weaving structure formed by the warp yarns 811, 812 and the insulating weft yarns 841 is satin or sateen. In the present embodiment, the interweaving of two adjacent insulating weft yarns 841 differ from one to another. In particular, the satin weave structure comprise a repetitive pattern of five insulating weft yarns 841, wherein the four insulating weft yarns on the left of the figure cross a first face 801 of the textile 800 to cover the electrically conductive warp yarns 811 and the fifth insulating weft yarn Z does not cover the electrically conductive warp yarns, thereby defining first electrical connection zones 814 at the first face 801 of the textile 800. The electrically conductive weft yarns may be interwoven in the multilayer warp in a similar manner as that described with reference to FIG. 1 or 5, thereby defining first electrical connection zones in the first face 801 of the textile 800. Electronic components may be connected to the first and second electrical connection zones in a similar as that described above with reference to FIGS. 1 and 2.

The sateen weave structure may be used for the entire fabric or for part of the fabric in combination with a plain weave structure.

It is to be noted that all the configurations described in the above described embodiments may be comprised within one single textile since it may be required to implement a textile having electrical connection zones at either one of or both faces, crossover points and via connections.

It is to be noted that in the embodiments described above more than one electrically conductive yarns of the first layer may also be arranged adjacent to each other and electrically separated from other adjacent electrically conductive yarns of the first layer by at least one electrically insulating yarn. In other words, each of the electrically conductive yarns of the first layer may be made of one or more electrically conductive yarns.

It is also to be understood that the number of insulating warp yarns electrically separating two adjacent electrically conductive warp yarns has been arbitrarily chosen in the embodiments described above and that other combinations are possible.

It is to be understood that the first face of the textile may be referred to as, using common terminology from the textile industry, the “face” of the fabric while the second face may be referred to as the “back” of the fabric. Alternatively, the first face may be referred to as the “top” of the fabric and the second face referred to as the “bottom” of the fabric.

It is also to be understood that the multilayer warp 101 may be made of more than three layers.

It is also to be noted that the warp and weft directions may be interchanged, thereby forming a textile comprising a multilayer weft having three or more layers and a warp comprising electrically conductive and insulating warp yarns interwoven within the yarns of the multilayer weft.

The present invention is applicable for all types of electronic and photonic multilayer textiles. In particular, the textile of the present invention may be used for soft lighting applications or wearable light therapy.

Although the invention above has been described in connection with preferred embodiments of the invention, it will be evident for a person skilled in the art that several modifications are conceivable without departing from the scope of the invention as defined by the following claims.

1. A textile formed of interwoven electrically conductive and insulating yarns arranged along a warp direction and a weft direction, comprising:
a multilayer warp comprising a first layer of electrically conductive yarns electrically separated from each other by at least one electrically insulating yarn, a second layer of electrically insulating yarns, and a third layer of electrically insulating yarns arranged between said first and second layers; wherein said first and second layers define a first face and a second face, respectively, of said multilayer warp; and
a weft comprising electrically conductive weft yarns electrically separated from each other by at least one electrically insulating weft yarn crossing said first face and covering the electrically conductive warp yarns of said first layer.

2. The textile as defined in claim 1, wherein at least one of said electrically conductive weft yarns is interwoven between said first and second faces of said multilayer warp and crosses at least one of said first and second faces by means of a loop arranged around a selected warp yarn (X, V1, V2, X1, X2, Y1, Y2) of at least one of said first and second layers, respectively.

3. The textile as defined in claim 1, wherein said second layer further comprises electrically conductive yarns electrically separated from each other by at least one of said electrically insulating yarns of said second layer, wherein said at least one electrically insulating weft yarn crosses said second face and covers the electrically conductive warp yarns of said second layer.

4. The textile as defined in claim 2, wherein said selected warp yarn (X, X1, X2) of at least one of said first and second layers is electrically insulating, thereby defining, by means of the loop, first electrical connection zones electrically separated from the electrically conductive warp yarns of said first and second layers, respectively, by at least one insulating warp yarn in each layer of said multi-layer warp, and thereby defining second connection zones at neighboring electrically conductive warp yarns of said at least one of said first and second layers, respectively.

5. The textile as defined in claim 4, wherein at least one electronic component is connected to said textile via said first and second electrical connection zones at said first or second face.

6. The textile as defined in claim 5, wherein said electronic component is at least one component of the group comprising a sensor, an actuator, an integrated circuit and an optoelectronic device.

7. The textile as defined in claim 5, wherein said electronic component is a light emitting diode.

8. The textile as defined in claim 4, wherein a plurality of electronic components are connected via said first and second connection zones at at least one of said first and second faces, wherein said electronic components are arranged in the form of an array.

9. The textile as defined in claim 8, wherein said array comprises a matrix of individually addressable electronic components.

10. The textile as defined in claim 5, further comprising a radio frequency antenna comprising woven conductive yarns in electrical connection with and for remote communication with the electronic components.

11. The textile as defined in claim 2, wherein said selected warp yarn (V1, V2, Y1, Y2) is electrically conductive, thereby forming a crossover point (314) or via connection in the textile.

12. The textile as defined in claim 1 wherein each of said at least one insulating weft yarn covers several adjacent warp yarns of at least one of said first and second layers, thereby forming a float.

13. The textile as defined in claim 1 wherein the structure formed by the warp and weft yarns is a satin or sateen weave structure, in which only some of the insulating weft yarns covers the electrically conductive warp yarns, thereby defining second electrical connection zones in the electrically conductive yarns of the first and/or second layers.
